(19) United States
(12) Patent Application Publication
(10) Pub. No.: US 2024/0395594 A1
(43) Pub. Date: Nov. 28, 2024

(54) APPARATUS FOR CHUCKING A WAFER

(71) Applicant: SAMSUNG ELECTRONICS CO., LTD., Suwon-si (KR)

(72) Inventors: Hungsuk YOU, Suwon-si (KR); Heejung Cho, Seoul (KR); Bumsoo Song, Seoul (KR); Kyoungran Kim, Suwon-si (KR); Joongha Lee, Suwon-si (KR)

(73) Assignee: PROTEC, Anyang-si (KR)

(21) Appl. No.: 18/539,834

(22) Filed: Dec. 14, 2023

(30) Foreign Application Priority Data
May 25, 2023 (KR) 10-2023-0067394

(51) Int. Cl. H01L 21/683; H01L 21/68

(52) U.S. Cl. CPC H01L 21/6838; H01L 21/681

(57) ABSTRACT

An apparatus for chucking a wafer, the apparatus including a vacuum chuck arranged under the wafer with a ring frame to fix the wafer using vacuum, a plurality of clampers directly making contact with the ring frame to downwardly compress the ring frame in a vertical direction, and a plurality of alignment blocks pushing the ring frame toward a central portion of the wafer in a horizontal direction to align the wafer.

### CROSS-REFERENCE TO RELATED APPLICATION

This application claims priority under 35 USC § 119 to Korean Patent Application No. 10-2023-0067394, filed on May 25, 2023, in the Korean Intellectual Property Office (KIPO), the contents of which are herein incorporated by reference in their entirety.

### BACKGROUND

### 1. Field

Example embodiments relate to an apparatus for chucking a wafer. More particularly, example embodiments relate to an apparatus for chucking a wafer with a ring frame.

### 2. Description of the Related Art

A wafer may be attached to a ring frame using an adhesive tape. In order to cut the wafer with the ring frame, the wafer may be chucked using vacuum.

### SUMMARY

Embodiments are directed to an apparatus for chucking a wafer, the apparatus including a vacuum chuck arranged under the wafer with a ring frame to fix the wafer using vacuum, a plurality of clampers directly making contact with the ring frame to downwardly compress the ring frame in a vertical direction, and a plurality of alignment blocks pushing the ring frame toward a central portion of the wafer in a horizontal direction to align the wafer.

Embodiments are directed to an apparatus for chucking a wafer, the apparatus including a vacuum chuck arranged under the wafer with a ring frame to fix the wafer using vacuum, a plurality of clampers directly making contact with the ring frame to downwardly compress the ring frame in a vertical direction, and a robot rotating the wafer with respect to the vertical direction to align the wafer.

Embodiments are directed to an apparatus for chucking a wafer, the apparatus including a vacuum chuck arranged under the wafer with a ring frame to fix the wafer using vacuum, and a robot directly making contact with the ring frame to downwardly compress the ring frame in a vertical direction and rotating the wafer with respect to the vertical direction to align the wafer.

### BRIEF DESCRIPTION OF THE DRAWINGS

Features will become apparent to those of skill in the art by describing in detail exemplary embodiments with reference to the attached drawings in which:

FIG. 1 is a plan view illustrating an apparatus for chucking a wafer in accordance with example embodiments;

FIG. 2 is a cross-sectional view taken along a line A-A′ in FIG. 1;

FIGS. 3 to 8 are plan views and cross-sectional views illustrating an operation of the apparatus in FIG. 1;

FIG. 9 is a plan view illustrating an apparatus for chucking a wafer in accordance with example embodiments;

FIG. 10 is a cross-sectional view taken along a line E-E′ in FIG. 9;

FIGS. 11 to 16 are plan views and cross-sectional views illustrating an operation of the apparatus in FIG. 19;

FIG. 17 is a plan view illustrating an apparatus for chucking a wafer in accordance with example embodiments;

FIG. 18 is a cross-sectional view taken along a line I-I′ in FIG. 17;

FIG. 19 is a cross-sectional view taken along a line J-J′ in FIG. 17; and

FIGS. 20 to 25 are plan views and cross-sectional views illustrating an operation of the apparatus in FIG. 17.

### DETAILED DESCRIPTION

Hereinafter, example embodiments will be explained in detail with reference to the accompanying drawings.

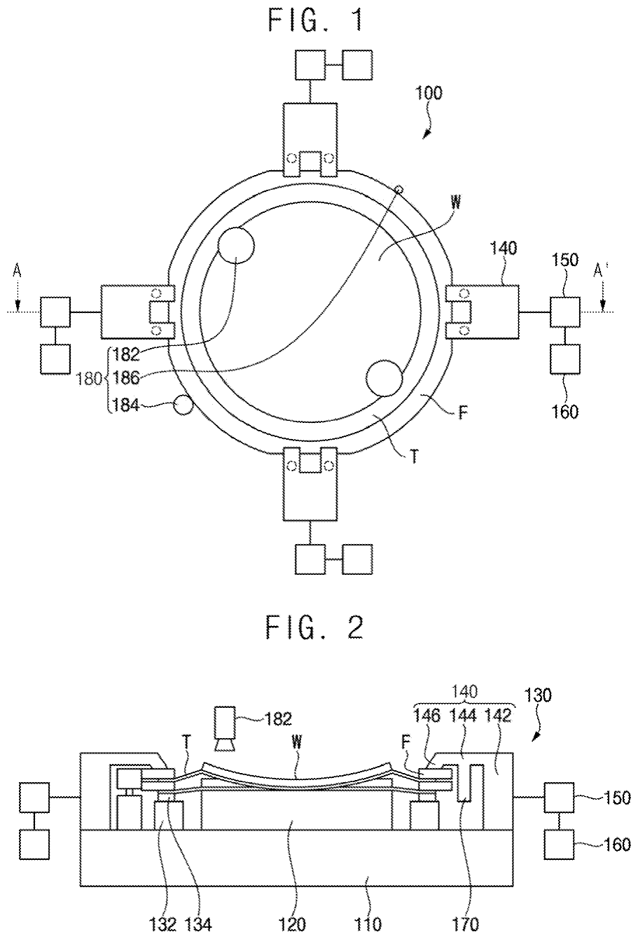

FIG. 1 is a plan view illustrating an apparatus for chucking a wafer in accordance with example embodiments and FIG. 2 is a cross-sectional view taken along a line A-A′ in FIG. 1.

An apparatus 100 for chucking a wafer in accordance with example embodiments may chuck a wafer W in a process for cutting the wafer W with a ring frame F applied to a fan-out type wafer level package. The apparatus 100 of example embodiments may be used for manufacturing other semiconductor packages.

Referring to FIGS. 1 and 2, the apparatus 100 may include a stage 110, a vacuum chuck 120, a plurality of clampers 130, a plurality of alignment blocks 170 and a rotary aligner 180.

The stage 110 may be arranged under the wafer W with the ring frame F. The ring frame F may be attached to an outer circumferential surface of the wafer W using an adhesive tape T. In an implementation, the adhesive tape T may be between the ring frame F and the wafer W.

The vacuum chuck 120 may be arranged on an upper surface of the stage 110. The wafer W with the ring frame F may be placed on an upper surface of the vacuum chuck 120. The vacuum chuck 120 may apply vacuum to the wafer W to fix the wafer W. When the wafer W is warped, the warped wafer W may not be firmly fixed to the vacuum chuck 120.

The clampers 130 may be arranged around the ring frame F. In example embodiments, the clampers 130 may be four spaced apart from each other by about 90 around the ring frame F. For example, as illustrated in FIG. 1, the clampers 130 may be a constant distance from one another, e.g., the clampers 130 may be spaced apart from each other by a uniform gap around the ring frame F. The clampers 130 may directly make contact with the ring frame F. The clampers 130 may downwardly, e.g., toward the stage 110, compress the ring frame F in a vertical direction to flatten the warped wafer W.

Each of the clampers 130 may include a clamping block 140, a horizontal actuator 150 and a vertical actuator 160. The clamping block 140 may directly make contact with the ring frame F. The horizontal actuator 150 may move the clamping block 140 in a horizontal direction. The vertical actuator 160 may move the clamping block 140 in the vertical direction.

The clamping block 140 may include a vertical block 142, a horizontal block 144 and a contact block 146. The vertical block 142 may be extended in the vertical direction adjacent to the ring frame F. The horizontal block 144 may be extended from an upper end of the vertical block 142 toward the ring frame F in the horizontal direction. The contact block 146 may be slantly, e.g., diagonally, extended from an end of the horizontal block 144 toward the ring frame F. The contact block 146 may selectively make contact with the ring frame F.

The horizontal actuator 150 may be connected to the vertical block 142 to move the vertical block 142 in the horizontal direction. The vertical actuator 160 may move the horizontal actuator 150 in the vertical direction. In an implementation, the vertical block 142 may be moved by the vertical actuator 160 in the vertical direction. In an implementation, the vertical actuator 160 may be connected to the vertical block 142. In an implementation, the horizontal actuator 150 may move the vertical actuator 160 in the horizontal direction. In an implementation, the horizontal actuator 150 and the vertical actuator 160 may be individually connected to the vertical block 142. The horizontal actuator 150 and the vertical actuator 160 may include a motor, a cylinder, and the like.

When the vertical actuator 160 downwardly moves the vertical block 142 in the vertical direction, the contact block 146 may downwardly compress an upper surface of the ring frame F. The ring frame F may be positioned on a support ring 132 on the upper surface of the stage 110. A resilient member 134 may be arranged on the support ring 132. Thus, the ring frame F compressed by the contact block 146 may be supported by the resilient member 135 to flatten the warped wafer W.

The horizontal actuator 150 may push the vertical block 142 in the horizontal direction toward a central portion of the wafer W. In an implementation, the wafer W may be accurately aligned on the upper surface of the vacuum chuck 120.

The alignment blocks 170 may be provided to the clamping block 140. In example embodiments, each of the alignment blocks 170 may be downwardly extended from a lower surface of the horizontal block 144 in the vertical direction. In an implementation, the alignment block 170 may be positioned between the vertical block 142 and the contact block 146.

When the horizontal actuator 150 pushes the vertical block 142 in the horizontal direction toward the central portion of the wafer W, an outer circumferential surface of the ring frame F may make contact with the alignment block 170. Because the alignment block 170 may be provided to the four clamping blocks 140 spaced apart from each other by about 90°, four points on the outer circumferential surface of the ring frame F spaced apart from each other by about 90° may closely make contact with the alignment blocks 170. In an implementation, the wafer W may be accurately aligned along two horizontal directions substantially perpendicular to each other. In an implementation, the alignment blocks 170 may function as a stopper in the horizontal direction.

The rotary aligner 180 may rotate the wafer W with respect to the vertical direction to align the wafer W. The rotary aligner 180 may include at least one camera 182, a rotary actuator 184 and at least one guide 186.

The camera 182 may be arranged over the wafer W. The camera 182 may photograph, e.g., image, an upper surface of the wafer W to obtain an image. In example embodiments, the camera 182 may include two cameras spaced apart from each other by about 180°.

The rotary actuator 184 may be arranged between the clamping blocks 140. The rotary actuator 184 may rotate the ring frame F with respect to the vertical direction based on the image obtained by the camera 182. In an implementation, the wafer W may be accurately aligned with respect to the vertical direction.

The guide 186 may guide the ring frame F rotated by the rotary actuator 184. In example embodiments, the guide 186 may be positioned at a region opposite to the rotary actuator 184 with respect to the central portion of the wafer W.

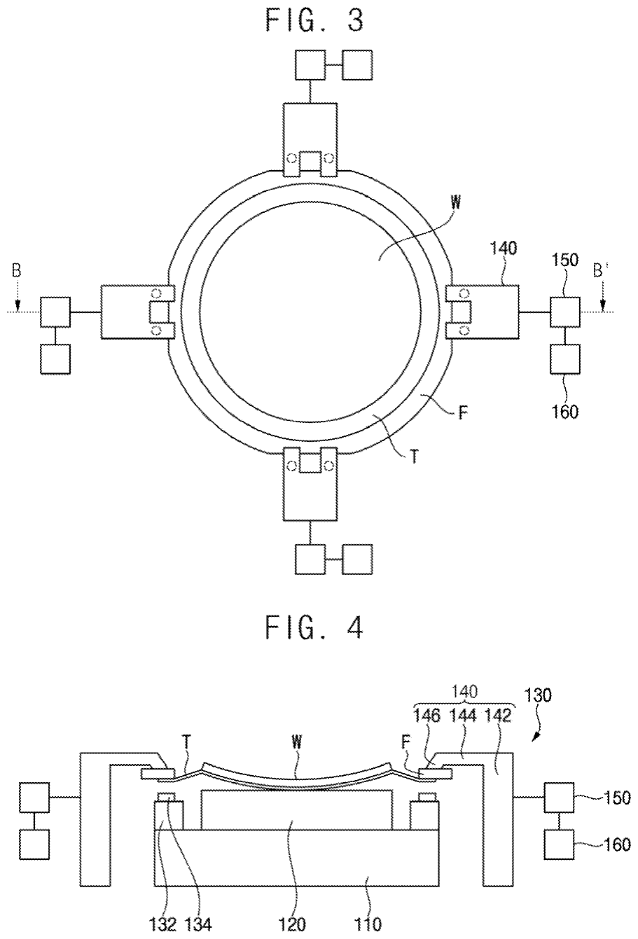

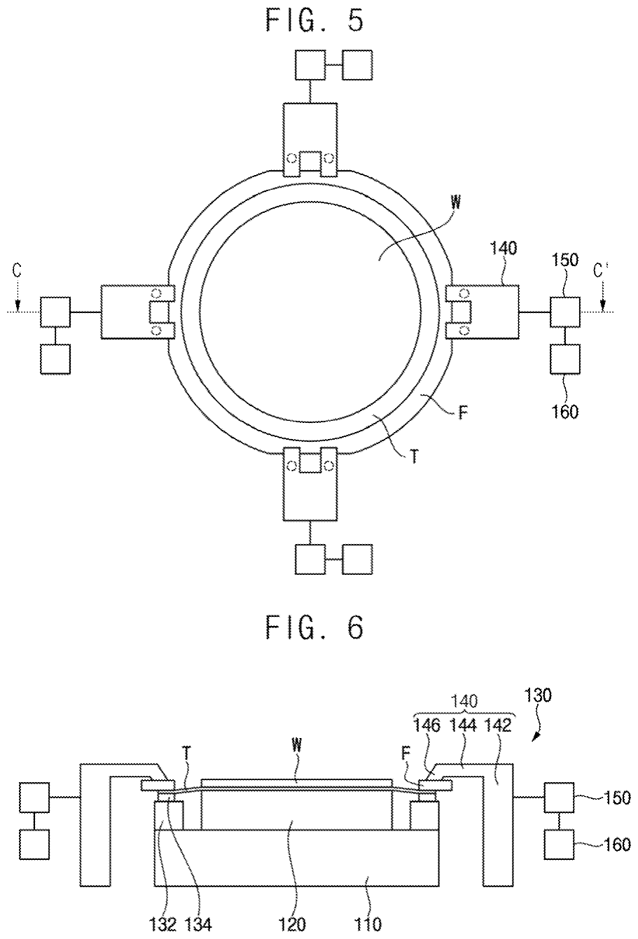

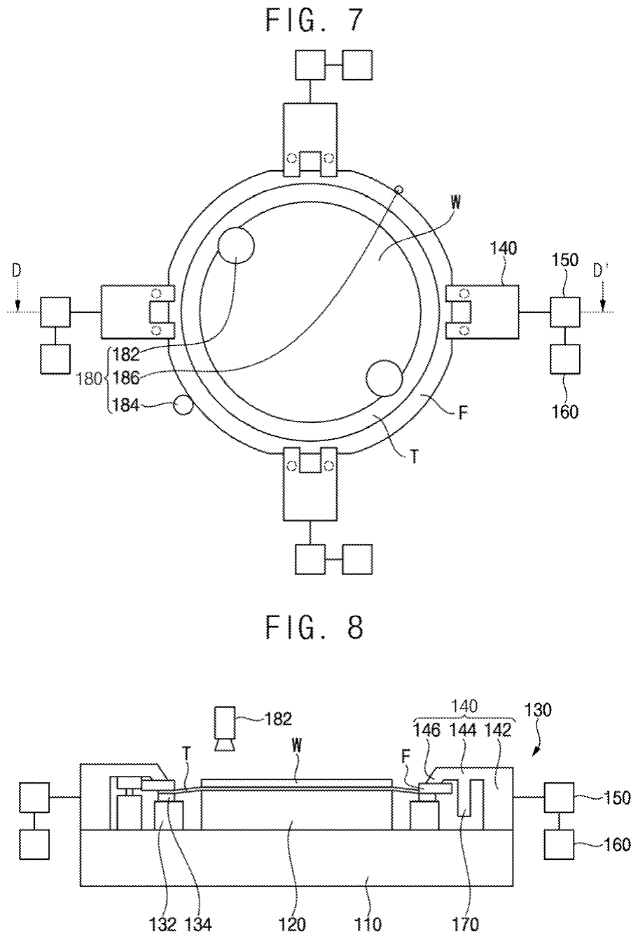

FIGS. 3 to 8 are plan views and cross-sectional views illustrating an operation of the apparatus in FIG. 1. FIG. 4 is a cross-sectional view taken along a line B-B′ in FIG. 3. FIG. 6 is a cross-sectional view taken along a line C-C′ in FIG. 5. FIG. 8 is a cross-sectional view taken along a line D-D′ in FIG. 7.

Referring to FIGS. 3 and 4, the four contact blocks 146 may make contact with the upper surface of the ring frame F provided to the warped wafer W.

Referring to FIGS. 5 and 6, the vertical actuator 160 may downwardly move the clamping block 140 in the vertical direction. Thus, the contact blocks 146 may downwardly compress the ring frame F in the vertical direction to flatten the warped wafer W. As a result, the flat entire lower surface of the wafer W may closely make contact with the upper surface of the vacuum chuck 120.

Referring to FIGS. 7 and 8, the horizontal actuators 150 may move the clamping blocks 140 in the horizontal direction toward the central portion of the wafer W. Thus, the outer circumferential surface of the ring frame F may closely make contact with, e.g., directly contact, the alignment blocks 170 to accurately align the wafer W.

In an implementation, the camera 182 may photograph the upper surface of the wafer W to obtain the image. The rotary actuator 184 may rotate the ring frame F with respect to the vertical direction based on the image obtained by the camera 182 to accurately align the wafer W with respect to the vertical direction.

The vacuum chuck 120 may apply the vacuum to the lower surface of the wafer W. In an implementation, the entire lower surface of the wafer W may be firmly fixed to the upper surface of the vacuum chuck 120.

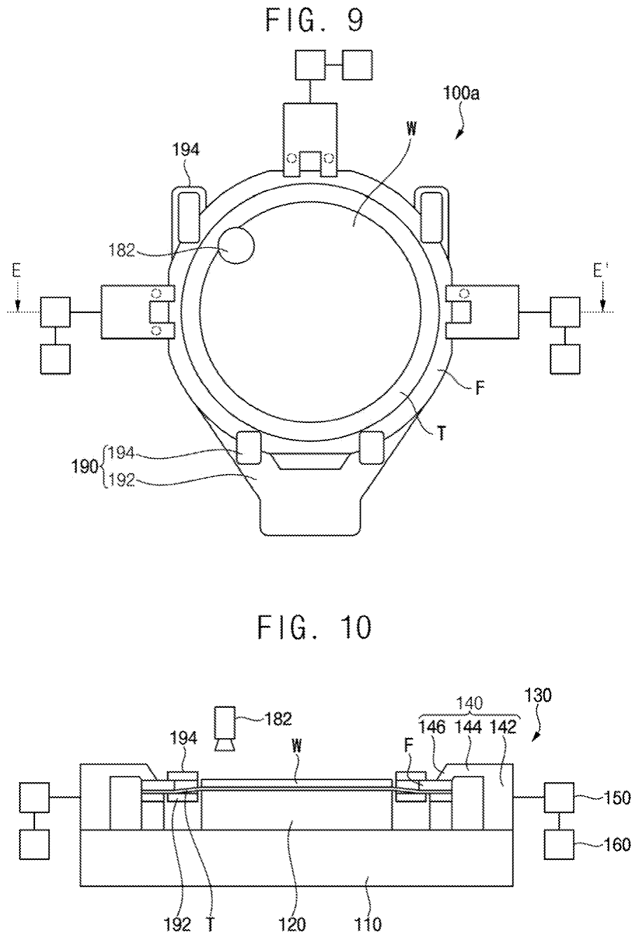

FIG. 9 is a plan view illustrating an apparatus for chucking a wafer in accordance with example embodiments and FIG. 10 is a cross-sectional view taken along a line E-E′ in FIG. 9.

An apparatus 100a for chucking a wafer in accordance with example embodiments may include elements substantially the same as those of the apparatus 100 in FIG. 1 except for a rotary aligner. Thus, the same reference numerals may refer to the same elements and any further illustrations with respect to the same elements may be omitted herein for brevity.

Referring to FIGS. 9 and 10, the apparatus 100a of example embodiments may include a robot 190. The robot 190 may include at least one camera 182, a robot arm 192 and a plurality of holders 194.

The camera 182 may be substantially the same as the camera 182 in FIG. 1. Thus, any further illustrations with respect to the camera 182 may be omitted herein for brevity.

In example embodiments, the clampers 130 may include the three clampers spaced apart from each other. In an implementation, any one of the four clampers 130 in FIG. 1 may be omitted.

The robot arm 192 may enter into a space under the wafer W through a region where the clamper 130 may not be positioned. The holders 194 may be arranged at the robot arm 192 to hold the ring frame F. Each of the holders 194 may selectively rotate the ring frame F with respect to the vertical direction based on the image obtained by the camera 182. In an implementation, an actuator for rotating the ring frame F with respect to the vertical direction may be provided to each of the holders 194. In example embodiments, the holders 194 may be the four holders for rotating four portions of the ring frame F.

In example embodiments, the robot 190 may be used in an equipment front end module (EFEM). The robot 190 may have the function as to load and unload the wafer W by a unit process. In an implementation, the robot used in the EFEM may be utilized in example embodiments.

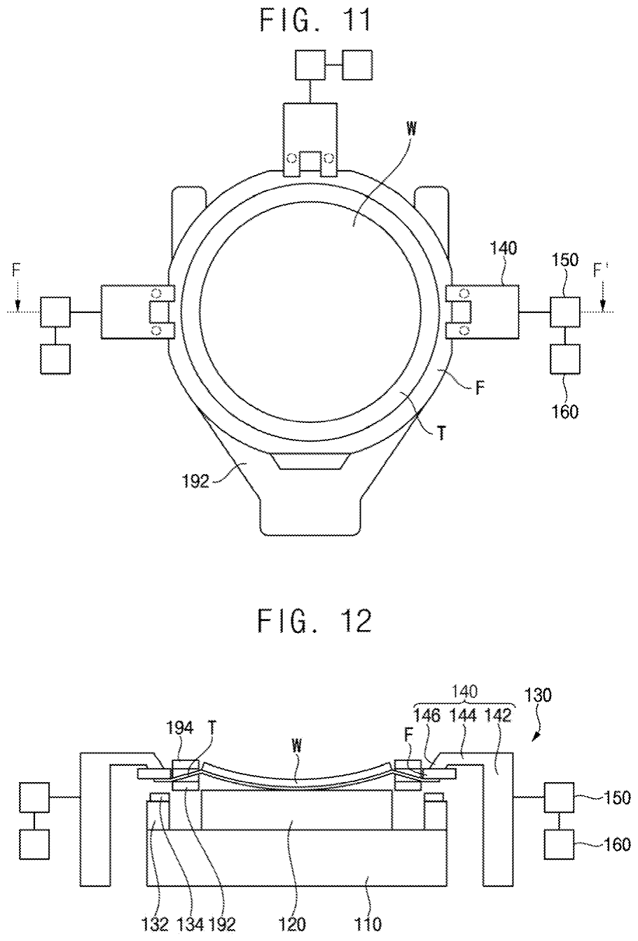

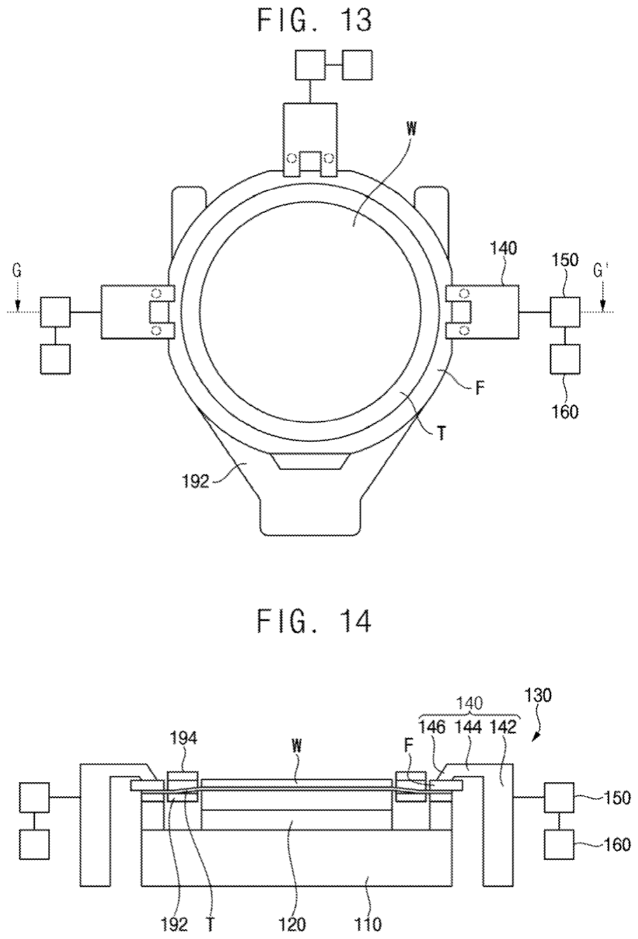

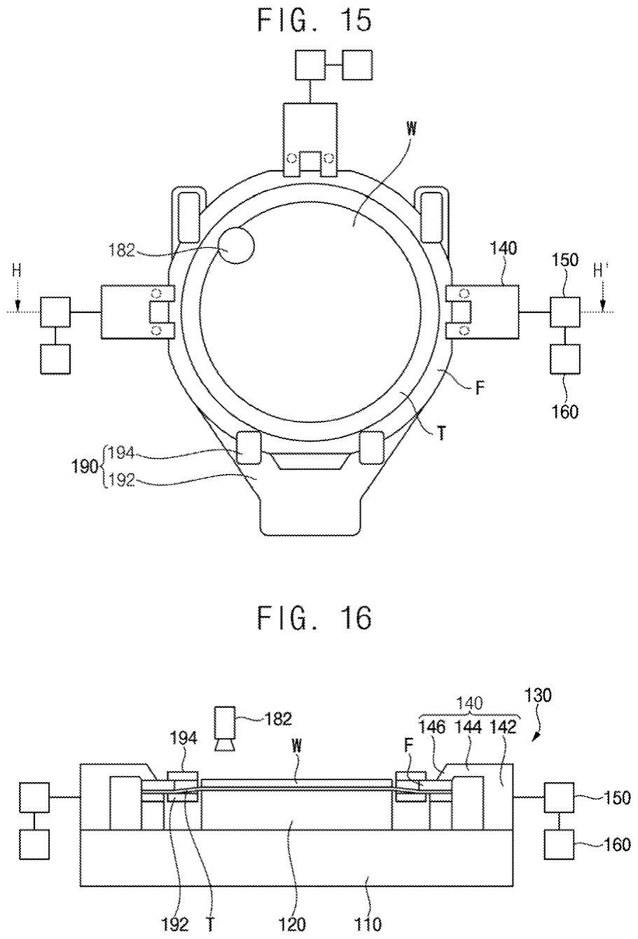

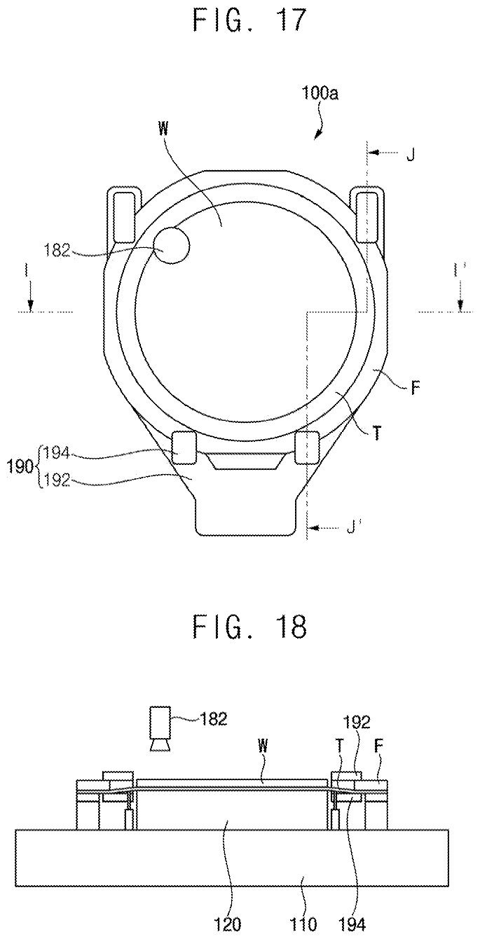

FIGS. 11 to 16 are plan views and cross-sectional views illustrating an operation of the apparatus in FIG. 19. FIG. 12 is a cross-sectional view taken along a line F-F′ in FIG. 11. FIG. 14 is a cross-sectional view taken along a line G-G′ in FIG. 13. FIG. 16 is a cross-sectional view taken along a line H-H′ in FIG. 15.

Referring to FIGS. 11 and 12, the three contact blocks 146 may make contact with the upper surface of the ring frame F provided to the warped wafer W.

Referring to FIGS. 13 and 14, the vertical actuator 160 may downwardly move the clamping block 140 in the vertical direction. Thus, the contact blocks 146 may downwardly compress the ring frame F in the vertical direction to flatten the warped wafer W. In an implementation, the flat entire lower surface of the wafer W may closely make contact with the upper surface of the vacuum chuck 120.

Referring to FIGS. 15 and 16, the horizontal actuators 150 may move the clamping blocks 140 in the horizontal direction toward the central portion of the wafer W. In an implementation, the outer circumferential surface of the ring frame F may closely make contact with the alignment blocks 170 to accurately align the wafer W.

Further, the camera 182 may photograph the upper surface of the wafer W to obtain the image. The holders 194 may rotate the ring frame F with respect to the vertical direction based on the image obtained by the camera 182 to accurately align the wafer W with respect to the vertical direction.

The vacuum chuck 120 may apply the vacuum to the lower surface of the wafer W. In an implementation, the entire lower surface of the wafer W may be firmly fixed to the upper surface of the vacuum chuck 120.

FIG. 17 is a plan view illustrating an apparatus for chucking a wafer in accordance with example embodiments, FIG. 18 is a cross-sectional view taken along a line I-I′ in FIG. 17 and FIG. 19 is a cross-sectional view taken along a line J-J′ in FIG. 17.

Referring to FIGS. 17 to 19, an apparatus 100b for chucking a wafer in accordance with example embodiments may include a vacuum chuck 120 and a robot 190. The vacuum chuck 120 may be substantially the same as the vacuum chuck 120 in FIG. 1. Thus, any further illustrations with respect to the vacuum chuck 120 may be omitted herein for brevity.

The robot 190 may have a structure and functions substantially the same as the structure and the functions of the robot 190 in FIG. 9. In an implementation, the robot 190 may directly make contact with the ring frame F to downwardly compress the ring frame F in the vertical direction.

The robot 190 used in the EFEM may have a structure configured to be moved in the horizontal direction and the vertical direction. In an implementation, the robot arm 192 may be moved in the horizontal direction and the vertical direction. The ring frame F may be downwardly compressed in the vertical direction using the functions of the robot arm 192. In an implementation, the apparatus 100b of example embodiments may not include the clamper 130 in FIG. 1.

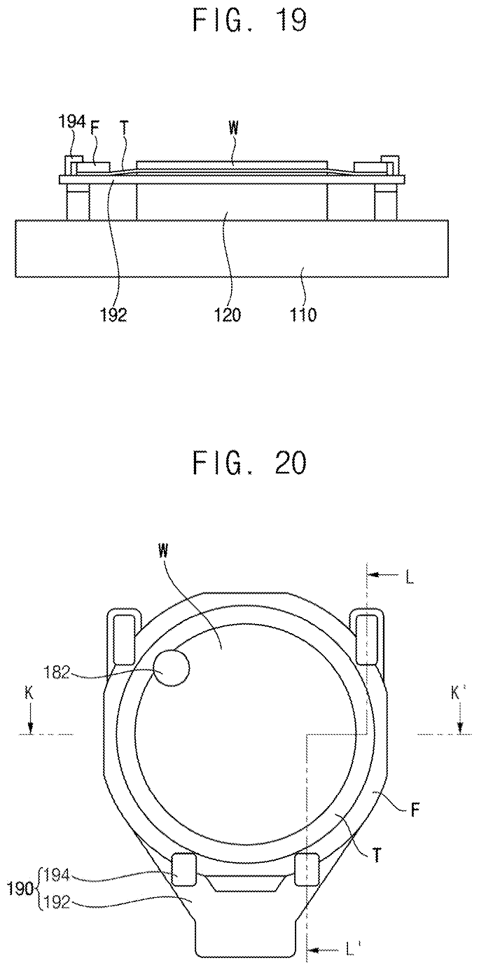

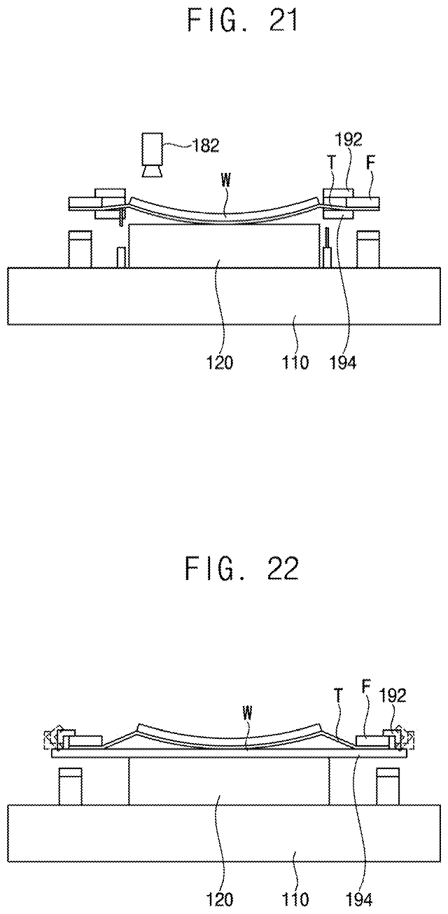

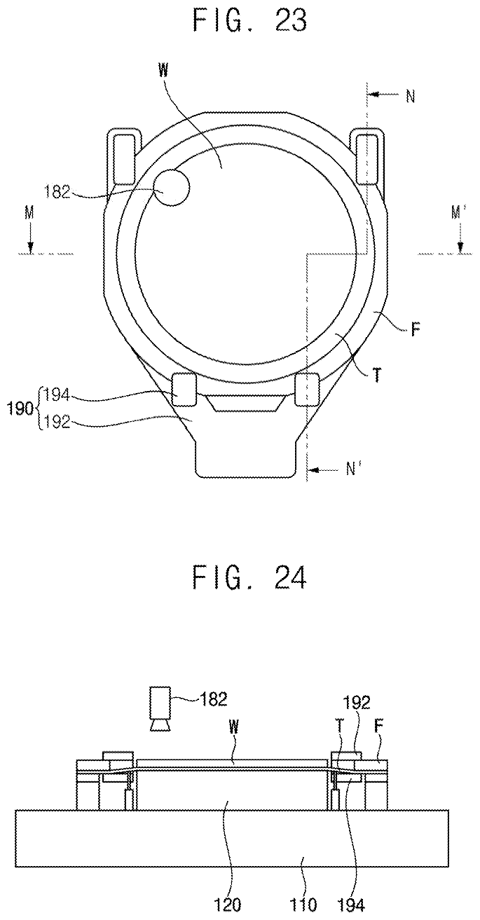

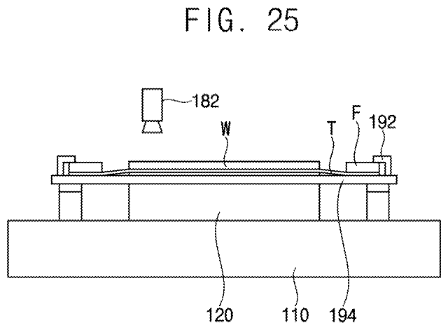

FIGS. 20 to 25 are plan views and cross-sectional views illustrating an operation of the apparatus in FIG. 17. FIG. 21 is a cross-sectional view taken along a line K-K′ in FIG. 20. FIG. 22 is a cross-sectional view taken along a line L-L′ in FIG. 20. FIG. 24 is a cross-sectional view taken along a line M-M′ in FIG. 23. FIG. 25 is a cross-sectional view taken along a line N-N′ in FIG. 23.

Referring to FIGS. 20 to 22, the robot arm 192 may downwardly move the holders 194 in the vertical direction. In an implementation, the holders 194 may downwardly compress the ring frame F in the vertical direction to flatten the warped wafer W. In an implementation, the flat entire lower surface of the wafer W may closely make contact with the upper surface of the vacuum chuck 120.

Referring to FIGS. 23 to 25, the robot arm 192 may move the holders 194 in the horizontal direction to accurately align the wafer.

In an implementation, the camera 182 may photograph the upper surface of the wafer W to obtain the image. The holders 194 may rotate the ring frame F with respect to the vertical direction based on the image obtained by the camera 182 to accurately align the wafer W with respect to the vertical direction.

The vacuum chuck 120 may apply the vacuum to the lower surface of the wafer W. In an implementation, the entire lower surface of the wafer W may be firmly fixed to the upper surface of the vacuum chuck 120.

According to example embodiments, the clampers may directly make contact with the ring frame, not the wafer. The clampers may downwardly compress the ring frame to flatten the warped wafer. In an implementation, the alignment blocks and/or the robot may accurately align the wafer. In an implementation, the apparatus may accurately chuck the wafer without a damage of the wafer. In another implementation, the robot may firmly chuck the ring frame and accurately align the wafer.

By way of summation and review, according to related arts, when a warpage may be generated in a wafer, a vacuum chuck may not accurately chuck the warped wafer. In order to accurately chuck the warped wafer, a pusher may be arranged over the warped wafer to downwardly compress the warped wafer. However, the pusher may make contact with the wafer and generate damage to the wafer. Example embodiments may provide an apparatus for accurately chucking a wafer without damaging the wafer.

According to example embodiments, the clampers may directly make contact with the ring frame, not the wafer. The clampers may downwardly compress the ring frame to flatten the warped wafer. Further, the alignment blocks and/or the robot may accurately align the wafer. Thus, the apparatus may accurately chuck the wafer without a damage of the wafer. In an implementation, the robot may firmly chuck the ring frame and accurately align the wafer.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An apparatus for chucking a wafer, the apparatus comprising:
a vacuum chuck arranged under the wafer with a ring frame to fix the wafer using vacuum;
a plurality of clampers directly making contact with the ring frame to downwardly compress the ring frame in a vertical direction; and
a plurality of alignment blocks pushing the ring frame in a direction oriented toward the vacuum chuck in a horizontal direction to align the wafer.

2. The apparatus of claim 1, wherein each of the plurality clampers are spaced apart from each other by a constant distance around the ring frame.

3. The apparatus of claim 2, wherein each of the plurality of clampers includes:
a clamping block positioned adjacent to the ring frame, and
a vertical actuator moving the clamping block in the vertical direction.

4. The apparatus of claim 3, wherein the clamping block includes:
a vertical block arranged outside the ring frame in the vertical direction,
a horizontal block extended from an upper end of the vertical block toward the ring frame in the horizontal direction, and
a contact block diagonally extended from an end of the horizontal block toward the ring frame and directly making contact with the ring frame.

5. The apparatus of claim 4, wherein one of the plurality of alignment blocks extends from a lower surface of the horizontal block in the vertical direction.

6. The apparatus of claim 3, wherein each of the plurality of clampers further includes a horizontal actuator moving the clamping block in the horizontal direction.

7. The apparatus of claim 1, further comprising a rotary aligner rotating the wafer with respect to the vertical direction to align the wafer.

8. The apparatus of claim 7, wherein the rotary aligner includes:
at least one camera photographing an upper surface of the wafer to obtain an image of the upper surface of the wafer, and
a rotary actuator selectively rotating the ring frame with respect to the vertical direction based on the image.

9. The apparatus of claim 8, wherein the rotary aligner further includes at least one guide guiding the ring frame rotated by the rotary actuator.

10. An apparatus for chucking a wafer, the apparatus comprising:
a vacuum chuck arranged under the wafer with a ring frame to fix the wafer using vacuum;
a plurality of clampers directly making contact with the ring frame to downwardly compress the ring frame in a vertical direction; and
a robot rotating the wafer with respect to the vertical direction to align the wafer.

11. The apparatus of claim 10, wherein the plurality of clampers includes three clampers spaced apart from each other.

12. The apparatus of claim 11, wherein the robot enters into a space under the wafer through a region where the plurality of clampers are not positioned.

13. The apparatus of claim 10, wherein each of the plurality of clampers includes:
a clamping block positioned adjacent to the ring frame,
a vertical actuator moving the clamping block in the vertical direction, and
a horizontal actuator moving the clamping block in a horizontal direction.

14. The apparatus of claim 13, wherein the clamping block includes:
a vertical block arranged outside the ring frame in the vertical direction,
a horizontal block extended from an upper end of the vertical block toward the ring frame in the horizontal direction, and
a contact block diagonally extended from an end of the horizontal block toward the ring frame and directly making contact with the ring frame.

15. The apparatus of claim 14, wherein the clamping block further includes an alignment block extended from a lower surface of the horizontal block in the vertical direction.

16. The apparatus of claim 10, wherein the robot includes:
at least one camera photographing an upper surface of the wafer to obtain an image of the upper surface of the wafer,
a robot arm supporting the wafer, and
at least one holder provided to the robot arm to selectively rotate the ring frame with respect to the vertical direction based on the image.

17. The apparatus of claim 16, wherein the at least one holder includes four holders rotating four portions of the ring frame.

18. An apparatus for chucking a wafer, the apparatus comprising:
a vacuum chuck arranged under the wafer with a ring frame to fix the wafer using vacuum; and
a robot directly making contact with the ring frame to downwardly compress the ring frame in a vertical direction and rotating the wafer with respect to the vertical direction to align the wafer.

19. The apparatus of claim 10, wherein the robot includes:
at least one camera photographing an upper surface of the wafer to obtain an image of the upper surface of the wafer,
at least one holder selectively rotating the ring frame with respect to the vertical direction based on the image, and
a robot arm moving the holder in the vertical direction.

20. The apparatus of claim 19, wherein the holder includes four holders rotating four portions of the ring frame.
